(19) United States
(12) Patent Application Publication
(10) Pub. No.: US 2024/0273260 A1
(43) Pub. Date: Aug. 15, 2024

(54) SYSTEMS AND METHODS CONFIGURED TO TRAIN AND UTILIZE A PRODUCT MODEL TO DETERMINE A CONFIGURATION OF A PROSPECTIVE PRODUCT

(71) Applicant: Disney Enterprises, Inc., Burbank, CA (US)

(72) Inventors: Alif Khalfan, Redwood City, CA (US); Brianna Cochran, Los Angeles, CA (US); David P. Min, Menlo Park, CA (US)

(21) Appl. No.: 18/169,618

(22) Filed: Feb. 15, 2023

(51) Int. Cl. G06F 30/27; G06F 30/10; G06Q 30/02

(52) U.S. Cl. CPC G06F 30/27; G06F 30/10; G06Q 30/0278

(57) ABSTRACT

Systems and methods configured to train a product model to determine a configuration of a prospective product are disclosed. Exemplary implementations may: obtain a product model; obtain training information from electronic storage; train the product model using the training information for individual developed products by using object information, subject information, and subject content information for the individual developed products as training inputs and product performance information as training outputs for the individual developed products such that the product model is trained to predict product performance information based on object information, subject information, and subject content information; store the trained product model to the electronic storage; receive target information for a prospective product; transmit the target information to the trained product model; receive object information and/or subject information for the prospective product; generate and transmit instructions for a fabrication system to generate the prospective product according to the received information.

### FIELD OF THE DISCLOSURE

The present disclosure relates to systems and methods configured to train and utilize a product model to determine a configuration of a prospective product.

### BACKGROUND

Typically, developing a prospective product requires at least a team of artists to submit concepts, a research team to determine subjects to integrate into the prospective product, and a development team to determine how to configure or build the prospective product. This manual process may be time consuming and limited to the information known by the individuals in the teams as opposed to a comprehensive database of information.

### SUMMARY

One aspect of the present disclosure relates to reducing the manual research and input from users to more intelligently and swiftly determine specific products to develop based on known information about previously developed products. First, a product model is trained based on information about objects that are the previously developed products, subjects featured on the previously developed products, content related to these subjects, and performance of the previously developed products. Thus, a trained product model is trained to recognize the correlations between the performance and the information behind the previously developed products. Secondly, the trained product model is utilized to recommend a prospective product. Target information is input to the trained product model and the trained product model output details that characterizes the prospective product as an object and/or the subjects to be incorporated on the object. Such output may be used to determine instructions for a fabrication system to generate a plurality of the prospective product. Therefore, errors in information that may be used as a basis for determinations may be reduced and products may be developed faster.

One aspect of the present disclosure relates to a system configured to train and utilize a product model to determine a configuration of a prospective product. The system may include one or more hardware processors configured by machine-readable instructions, electronic storage, and/or other elements. Server(s) may be configured by machine-readable instructions that include one or more instruction components. The instruction components may include computer program components. The instruction components may include one or more of obtainment component, model training component, target receiving component, model utilization component, instruction component, and/or other instruction components.

The electronic storage may store the product model, training information, and/or other information. The training information may include, for individual developed products, (i) object information characterizing a developed product, (ii) product performance information representing performance of the product after release, (iii) subject information indicating individual subjects of the developed product, (iv) subject content information related to content related to the subject, and/or other training information.

The obtainment component may be configured to obtain a product model. The product model may be obtained from the electronic storage. The obtainment component may be configured to obtain the training information from the electronic storage.

The model training component may be configured to train the product model using the training information for the individual developed products. That is, by using the object information, subject information, and subject content information for the individual developed products as training inputs and the product performance information as training outputs for the individual developed products, the product model may be trained. As such, the product model is trained to predict the product performance information based on the object information, the subject information, and the subject content information. The model training component may be configured to store the trained product model to the electronic storage.

The target receiving component may be configured to receive target information for a prospective product. The target information may generally characterize the prospective product as an object and a subject of the object.

The model utilization component may be configured to transmit the target information to the trained product model so that the trained product model identifies at least object information for the prospective product and/or subject information for the prospective product based on the target information.

The instruction component may be configured to receive the object information for the prospective product and/or the subject information for the prospective product. Subsequently, the instruction component may be configured to generate instructions for a fabrication system to generate the prospective product in accordance with the object information or the prospective product and/or the subject information or the prospective product. The instruction component may be configured to transmit the instructions to the fabrication system.

As used herein, the term “obtain” (and derivatives thereof) may include active and/or passive retrieval, determination, derivation, transfer, upload, download, submission, and/or exchange of information, and/or any combination thereof. As used herein, the term “effectuate” (and derivatives thereof) may include active and/or passive causation of any effect, both local and remote. As used herein, the term “determine” (and derivatives thereof) may include measure, calculate, compute, estimate, approximate, generate, and/or otherwise derive, and/or any combination thereof.

These and other features, and characteristics of the present technology, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention. As used in the specification and in the claims, the singular form of ‘a’, ‘an’, and ‘the’ include plural referents unless the context clearly dictates otherwise.

### BRIEF DESCRIPTION OF THE DRAWINGS

FIG. 1 illustrates a system configured to train and utilize a product model to determine a configuration of a prospective product, in accordance with one or more implementations.

FIG. 2 illustrates a method configured to utilize a trained product model to determine instructions for a fabrication system to generate a product based on a product request, in accordance with one or more implementations.

FIG. 3A-3B illustrates a system configured to train and utilize a product model to determine a configuration of a prospective product, in accordance with one or more implementations.

### DETAILED DESCRIPTION

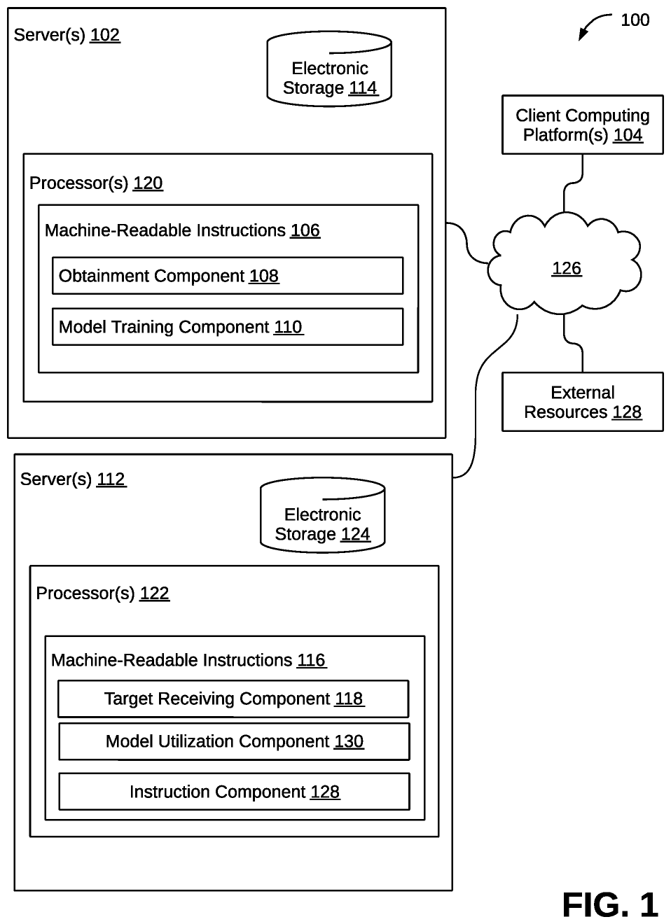

FIG. 1 illustrates a system 100 configured to train a product model to determine a configuration of a prospective product, in accordance with one or more implementations. In some implementations, system 100 may include one or more servers 102, electronic storage 114, servers 112, electronic storage 124, and/or other elements. Server(s) 102 and 112 may be configured to communicate with one or more client computing platforms 104 according to a client/server architecture and/or other architectures. Client computing platform(s) 104 may be configured to communicate with other client computing platforms via server(s) 102 and 112 and/or according to a peer-to-peer architecture and/or other architectures. Users may access system 100 via client computing platform(s) 104.

Electronic storage 114 may store a product model, training information, and/or other information. The training information may include, for individual developed products, object information characterizing a developed product, product performance information representing performance of the product after release, subject information indicating individual subjects of the developed product, subject content information related to content related to the subject, and/or other training information. The developed products may refer to objects and/or content that has been established, whether released for consumers or unreleased. By way of non-limiting example, products may include clothing items (e.g., t-shirts, pants, socks), shoes, accessories (e.g., bags, jewelry), toys, collectables, furniture, motor vehicles, food, beverages, bedding, and/or other various products. By way of non-limiting example, the content may include television shows, movies, short films, short form videos, mobile applications, books, comics, and/or other content.

The object information may include a product type of the object, a product specification, a product demographic, manufacturing information for the developed product, and/or other object information. The product type may be, by way of non-limiting example, a particular clothing item, clothing generally, luxury shoes, a lunch box, a backpack, a bag or purse, bedding, a toy, a phone case, among other product types. The product specification may include directions to use the object, dimensions of the object, a weight of the object, one or more colors of the object, an amount of pieces that the object includes, a maximum speed, among other product specifications. The product demographic may refer to an age or other demographic group that the object pertains to. The manufacturing information may include one or more materials that make up the object, a price per object unit to manufacture, an amount of time to manufacture one object unit or a particular amount of object units, one or more sources of the one or more materials, cost to obtain the one or more sources, manufacturing location, and/or other manufacturing information.

The product performance information may include a product launch date, a product discontinuation date, revenue from a start date, a volume of sales from the start date, a wholesale manufacturing price, manufacturers suggest retail price (MSRP) over time from the start date, demographic information of consumers, one or more geographic regions that sold or provided accessibility to the products, a geographic region with most sales, and one or more retailers that sell the individual previous products. The product launch date may be a date on which the product was released and accessible to the consumers. The product discontinuation date, if one exists, may be a date that the product was removed from accessibility by the consumers or the date that manufacturing of the product ceased. The revenue from the start date may be an amount of consideration earned from sales of the product and/or advertisements associated with the product beginning on the start date, such as the product launch date or a date that a sale of the product first occurred. The volume of sales from the start date may be an amount of sales that have occurred beginning on the start date. The wholesale manufacturing price may be a price that is based on the materials, labor, and/or other factors that a manufacturer of the product charges an entity ordering the products. The MSRP over time may be a recommended price of the individual products by the manufacturer as it may change over time while the product is accessible for consumption. The demographic information of the consumers may indicate one or more groups of people (e.g., age groups, regions, countries, ethnicities) that actually consumed, purchased, or otherwise obtained the product. The one or more retailers may be ones that sell and provide the access to the products to the consumers.

The subject information may include a subject definition for the individual subjects, licensed art styles incorporated into or with the subjects, and/or other subject information. A subject may be a focus or a feature of the object. For example, the subject may be particular character from a movie. The subject definition may include motivations of the subject, one or more personalities of the subject, physical characteristics of the subject (e.g., facial structure, hairdo, facial hair, height, measurements, color of skin or fur), a background story of the subject, a fashion style of the subject, and/or other subject definitions. Individual features included in the subject definition may be associated with a date on which the individual features changed (e.g., hairdo changed, suit changed). The licensed art styles may refer to particular renderings of the subject. In some implementations, the individual renderings of the subject may be associated with a date that it was created and/or changed. For example, individual renderings of the subject may vary based on a year or a decade that the renderings were illustrated or otherwise generated.

The subject content information may include schedules for releases of one or more upcoming or past collections for all media types related to the one or more subjects, one or more budgets for the releases of the upcoming or past collections, and/or other subject content information. A release may refer to accessibility for consumption by consumers. A collection may include more than one related subject that often are presented together, for example, characters within a movie franchise, among others. In some implementations, the individual subjects may be included in one or more collections. The media types may include video, image, television, print, products, amusement park attractions, among others. The one or more budgets for the releases of the upcoming or past collections may refer to an amount of funds available for planning and/or marketing the releases. For the past collections, the budgets for the releases may indicate remaining funds, overspending, and/or debt.

In some implementations, the subject content information may further include research information. The research information may include demographic research on the upcoming releases of content and/or products related to the individual collections, revenue forecast for the releases of the content and/or products, market shares by product type, and/or other subject content information. The demographic research on the upcoming releases of content and/or products related to individual collections may indicate one or more groups of people that are likely and unlikely to consume upcoming content and/or products of various individual collections. The revenue forecast for the releases of the content and/or products may indicate predictions of an amount of consideration that may be earned from sales, subscriptions, downloads, associated advertisements, among other revenue. The market shares by product type may indicate individual portions of a market that are controlled by or have a strong presence of individual product types. For example, the clothing product type may control 15% of the market, toys may control 70% of the market, and bedding may control 15% of the market.

Server(s) 102 may be configured by machine-readable instructions 106. Machine-readable instructions 106 may include one or more instruction components. The instruction components may include computer program components. The instruction components may include one or more of obtainment component 108, model training component 110, and/or other instruction components.

Obtainment component 108 may be configured to obtain the product model. The product model may be obtained from electronic storage 114 and/or other electronic storage. Obtainment component 108 may be configured to obtain the training information and/or other information from electronic storage 114.

Model training component 110 may be configured to train the product model using the training information for the individual developed products. That is, the product model may use the object information, the subject information, and subject content information for the individual developed products as training inputs and corresponding the product performance information for the individual developed products as training outputs. The training inputs and the training outputs may be information that are closely correlated. The training inputs may be information that caused the training outputs. As such, the product model may be trained to predict product performance information for other products, such as prospective products, based on object information, subject information, and subject content information for the prospective products. Subsequent to the training, model training component 110 may be configured to store the trained product model to electronic storage 114, electronic storage 124, and/or other storage.

Electronic storage 124 may be similar as electronic storage 114 described herein, but included in server(s) 112. In some implementations, electronic storage 124 and electronic storage 114 may communicate via network 126 or may be the same storage media, and thus store the same information. Electronic storage 124, and/or electronic storage 114, may store the trained product model trained to predict the product performance information based on the object information, the subject information, and the subject content information, and recommend at least the object information and the subject information for a prospective product to achieve maximum performance. Maximum performance may refer to a maximum amount of prospective product units sold, a maximum revenue, a maximum time the prospective product is manufactured and accessible to the consumers, and/or other maximum performance parameters.

Server(s) 112 may be configured by machine-readable instructions 116. Machine-readable instructions 116 may include one or more instruction components. As described herein, server(s) 112 may be similar to server(s) 102, and machine-readable instructions 116 may be similar to machine-readable instructions 106 but configured for server(s) 112. The instruction components may include one or more of target receiving component 118, model utilization component 130, instruction component 128, and/or other instruction components. In some implementations, components 118, 130, and/or 128 may be included in as machine-readable instructions 106, therefore the functionality of all the components are executed by server(s) 102. In some implementations, components 108 and 110 may be included in as machine-readable instructions 116, therefore the functionality of all the components are executed by server(s) 112.

Target receiving component 118 may be configured to receive target information for a prospective product. In some implementations, the target information may be received from client computing platform 104 associated with an administrative user or other users. The prospective product may be an object that the administrative user or other users request to be determined to manufacture and future release. The administrative user may be a designated user of the trained product model. The target information may generally characterize the prospective product as an object and a subject of the object. For example, the target information may include a particular movie character and a lunch box as the product type.

In some implementations, the target information may include a target demographic(s), a target price point or MSRP range for a unit of the prospective product, target region, the product type, an intensity value to implementation of the subject definitions, the licensed art style, a weight value for the licensed art style, one or more target collections, and/or other target information. The target demographic(s) may be one or more groups of people that the prospective product is to be directed to. The MSRP range for the unit of the prospective product may be a target price range for a retail price of the prospective product that the manufacturer suggested. The MSRP range may be restricted to span a particular amount between a minimum price and a maximum price. For example, the MSRP range may be restricted to span $10, thus the MSRP range may be $14-$24, but not $14-$40. The target region may be a geographical area that the prospective product may be sought to be available in or may be logical to be available in (e.g., raincoats for year-round rainy areas).

The intensity value to implementation of the subject definitions may be a value that represent how intense or strong the subject definitions should be applied to the subjects of the prospective content. The intensity value may be a value from a fixed range. For example, a low intensity value of 1 of a range from 1-5 may enable more autonomy for the trained product model to determine the subjects to incorporate, and particular portions of the subject definitions to implement for the prospective product. As another example, a high intensity value of 5 of the range from 1-5 may require the trained product model to determine subjects to incorporate into the prospective product and implement them exactly as the subject definitions define them. The weight value for the licensed art style may be value that represents how intense or strong a presence of the licensed art style is to be on the prospective product. Similar to the intensity value, the weight value may be a value from a fixed range. The one or more target collections may be one or more of the collections that are requested, and thus one or more subjects from the one or more collections may be incorporated into the prospective product.

Model utilization component 130 may be configured to transmit the target information to the trained product model. Thus, the trained product model may identify at least the object information for the prospective product, the subject information for the prospective product, and/or other information based on the target information. In some implementations, the trained product model may further determine prospective performance information for the prospective product.

The prospective performance information may include the target demographic, a target geographic region to offer the prospective product in, a recommended wholesale manufacturing price point, a target MSRP, a recommended product launch date, an estimated achievable revenue, and an estimated amount of time in market, and/or other prospective performance information. The target geographic region may be a geographic region that the prospective product is recommended to be particularly offered in. In some implementations, the target geographic region may be determined based on cost to ship to the retailers of the target geographic region (e.g., packaging, fuel, labor), wage for employees at the retailers, the demographic of the geographic region, and/or other factors. The recommended wholesale manufacturing price may be the wholesale manufacturing price that is recommended to agree upon with the manufacturer(s). The target MSRP may be the retail price for the prospective product suggested by the manufacturers to be achieved. Thus, the entity ordering from the manufacturers may determine an actual retail price based on the target MSRP. The recommended product launch date may be a date on which the prospective product is made available to consumers via the retailers, whether in-person or online. The estimated achievable revenue may refer to an earned amount of consideration that is estimated to be achievable by sales, downloads, associated advertisements, among others with the prospective product. The estimated amount of time in market may refer to an amount of time estimated that the prospective product may be accessible for consumption by the consumers via the retailers, whether in-person or online.

Model utilization component 130 may be configured to receive the object information and/or the subject information, and/or other information for the prospective product that is determined by the trained product model.

Instruction component 128 may be configured to generate instructions for a fabrication system to generate the prospective product in accordance with the object information the subject information, and/or other information. The fabrication system may be a system managed by the manufacturers, a network-connected machine, and/or other fabrication system capable of physically generating products. For example, the fabrication systems may include a three-dimensional printer, a mold generator, a mold injector, among others. In some implementations, the fabrication system may be external to system 100. In some implementations, the fabrication system may be included in system 100. Nonetheless, instruction component 128 may be configured to transmit the instructions to the fabrication system via network 126.

In some implementations, the generated instructions may include one or more computer-aided designs in addition to instructions for one or more persons to manually collect articles, measure, cut, create, and/or assemble the prospective product or plurality thereof. In some implementations, the generated instructions may include one or more machines, one or more materials, an amount of personnel, a warehouse size, and/or other elements required to fabricate a plurality of the prospective product. Such generated instructions may be presented to one or more users of system 100 via client computing platform(s) 104.

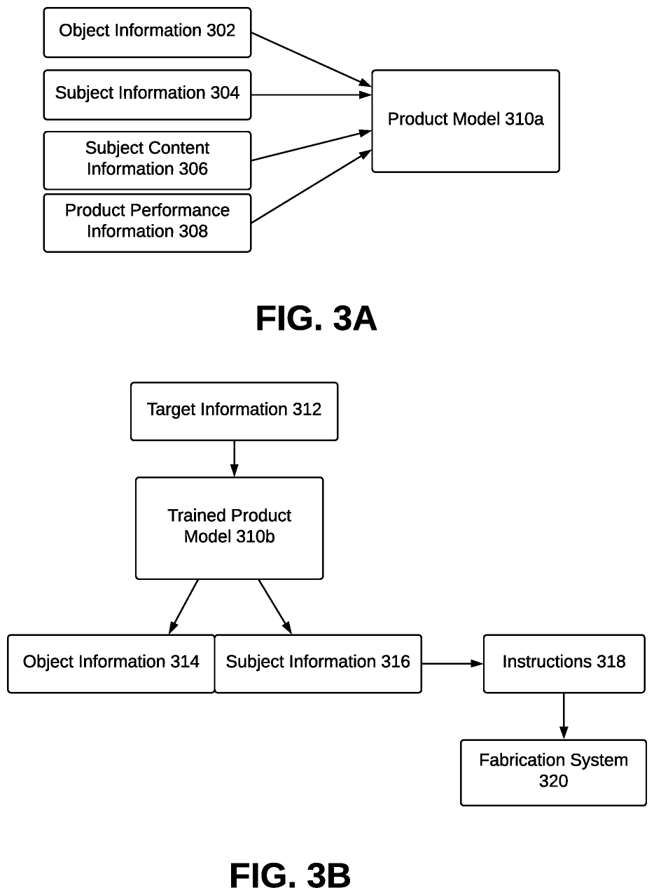

FIG. 3A illustrates object information 302, subject information 304, and subject content information 306, and product performance information 308 that may be obtained and used to the train product model 310a. Object information 302, subject information 304, and subject content information 306 for individual developed products may be obtained and used as training inputs for product model 310a. Product performance information 308 for the individual developed products may be obtained and used as corresponding training outputs. Thus, product model 310a may be trained to predict product performance information for prospective products based on object information, subject information, and subject content information for the prospective products.

FIG. 3B illustrates trained product model 310b subsequent to the training described in FIG. 3A. Target information 312 that generally characterizes a prospective product may be input into trained product model 310b. Trained product model 310b may subsequently output object information 314 that characterizes the prospective product and subject information 316 that indicates one or more subjects for the prospective product. Object information 314 and subject information 316 may be the basis of generating instructions 318 for fabrication system 320 to generate the prospective product. Instructions 318 may be transmitted to fabrication system 320 to execute, and thus generate the prospective product.

In some implementations, server(s) 102, client computing platform(s) 104, and/or external resources 132 may be operatively linked via one or more electronic communication links. For example, such electronic communication links may be established, at least in part, via network 126 such as the Internet and/or other networks. It will be appreciated that this is not intended to be limiting, and that the scope of this disclosure includes implementations in which server(s) 102, client computing platform(s) 104, and/or external resources 132 may be operatively linked via some other communication media.

A given client computing platform 104 may include one or more processors configured to execute computer program components. The computer program components may be configured to enable an expert or user associated with the given client computing platform 104 to interface with system 100 and/or external resources 132, and/or provide other functionality attributed herein to client computing platform(s) 104. By way of non-limiting example, the given client computing platform 104 may include one or more of a desktop computer, a laptop computer, a handheld computer, a tablet computing platform, a NetBook, a Smartphone, a gaming console, and/or other computing platforms.

External resources 132 may include sources of information outside of system 100, external entities participating with system 100, and/or other resources. In some implementations, some or all of the functionality attributed herein to external resources 132 may be provided by resources included in system 100.

Server(s) 102 may include electronic storage 114, one or more processors 120, and/or other components. Server(s) 112 may include electronic storage 124, one or more processors 122, and/or other components that are similar to electronic storage 114, one or more processors 120, and/or other components, respectively, described herein. Server(s) 102 and/or 112 may include communication lines, or ports to enable the exchange of information with network 126 and/or other computing platforms. Illustration of server(s) 102 and/or 112 in FIG. 1 is not intended to be limiting. Server(s) 102 and/or 112 may include a plurality of hardware, software, and/or firmware components operating together to provide the functionality attributed herein to server(s) 102 and/or 112. For example, server(s) 102 and/or 112 may be implemented by a cloud of computing platforms operating together as server(s) 102 and/or 112.

Electronic storage 114 may comprise non-transitory storage media that electronically stores information. The electronic storage media of electronic storage 114 may include one or both of system storage that is provided integrally (i.e., substantially non-removable) with server(s) 102 and/or removable storage that is removably connectable to server(s) 102 via, for example, a port (e.g., a USB port, a firewire port, etc.) or a drive (e.g., a disk drive, etc.). Electronic storage 114 may include one or more of optically readable storage media (e.g., optical disks, etc.), magnetically readable storage media (e.g., magnetic tape, magnetic hard drive, floppy drive, etc.), electrical charge-based storage media (e.g., EEPROM, RAM, etc.), solid-state storage media (e.g., flash drive, etc.), and/or other electronically readable storage media. Electronic storage 114 may include one or more virtual storage resources (e.g., cloud storage, a virtual private network, and/or other virtual storage resources). Electronic storage 114 may store software algorithms, information determined by processor(s) 120, information received from server(s) 102, information received from client computing platform(s) 104, and/or other information that enables server(s) 102 to function as described herein.

Processor(s) 120 may be configured to provide information processing capabilities in server(s) 102. As such, processor(s) 120 may include one or more of a digital processor, an analog processor, a digital circuit designed to process information, an analog circuit designed to process information, a state machine, and/or other mechanisms for electronically processing information. Although processor(s) 120 is shown in FIG. 1 as a single entity, this is for illustrative purposes only. In some implementations, processor(s) 120 may include a plurality of processing units. These processing units may be physically located within the same device, or processor(s) 120 may represent processing functionality of a plurality of devices operating in coordination. Processor(s) 122 may be similar to processor(s) 120 described herein but configured to provide information processing capabilities in server(s) 112.

Processor(s) 120 may be configured to execute components 108, 110, 118, 130, and/or 128, and/or other components. Processor(s) 120 may be configured to execute components 108, 110, 118, 130, and/or 128, and/or other components by software; hardware; firmware; some combination of software, hardware, and/or firmware; and/or other mechanisms for configuring processing capabilities on processor(s) 120. As used herein, the term “component” may refer to any component or set of components that perform the functionality attributed to the component. This may include one or more physical processors during execution of processor readable instructions, the processor readable instructions, circuitry, hardware, storage media, or any other components.

It should be appreciated that although components 108, 110, 118, 130, and/or 128 are illustrated in FIG. 1 as being implemented within multiple processing units, in implementations in which processor(s) 120 and 122 are a single processing unit, one or more of components 108, 110, 118, 130, and/or 128 may be implemented together with the other components. The description of the functionality provided by the different components 108, 110, 118, 130, and/or 128 described below is for illustrative purposes, and is not intended to be limiting, as any of components 108, 110, 118, 130, and/or 128 may provide more or less functionality than is described. For example, one or more of components 108, 110, 118, 130, and/or 128 may be eliminated, and some or all of its functionality may be provided by other ones of components 108, 110, 118, 130, and/or 128. As another example, processor(s) 120 may be configured to execute one or more additional components that may perform some or all of the functionality attributed below to one of components 108, 110, 118, 130, and/or 128.

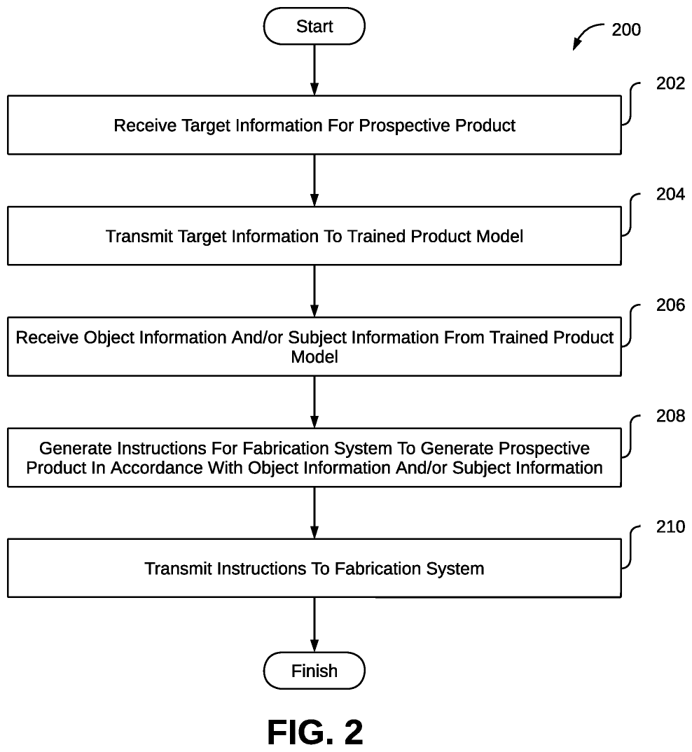

FIG. 2 illustrates a method 200 to instruct a fabrication system to generate a product based on a product request, in accordance with one or more implementations. The operations of method 200 presented below are intended to be illustrative. In some implementations, method 200 may be accomplished with one or more additional operations not described, and/or without one or more of the operations discussed. Additionally, the order in which the operations of method 200 are illustrated in FIG. 2 and described below is not intended to be limiting.

In some implementations, method 200 may be implemented in one or more processing devices (e.g., a digital processor, an analog processor, a digital circuit designed to process information, an analog circuit designed to process information, a state machine, and/or other mechanisms for electronically processing information). The one or more processing devices may include one or more devices executing some or all of the operations of method 200 in response to instructions stored electronically on an electronic storage medium. The one or more processing devices may include one or more devices configured through hardware, firmware, and/or software to be specifically designed for execution of one or more of the operations of method 200.

An operation 202 may include receiving target information for a prospective product. The target information may characterize the prospective product as an object and a subject of the object. Operation 202 may be performed by one or more hardware processors configured by machine-readable instructions including a component that is the same as or similar to target receiving component 118, in accordance with one or more implementations.

An operation 204 may include transmitting the target information to the trained product model. Electronic storage may store the trained product model trained to predict product performance information based on object information, subject information, and subject content information and recommend at least the object information and the subject information for a prospective product to achieve maximum performance. Thus, the trained product model identifies at least object information for the prospective product and/or subject information for the prospective product based on the target information. Operation 204 may be performed by one or more hardware processors configured by machine-readable instructions including a component that is the same as or similar to model utilization component 130, in accordance with one or more implementations.

An operation 206 may include receiving the object information and/or the subject information. Operation 206 may be performed by one or more hardware processors configured by machine-readable instructions including a component that is the same as or similar to model utilization component 130, in accordance with one or more implementations.

An operation 208 may include generating instructions for a fabrication system to generate the prospective product in accordance with the object information and/or the subject information. Operation 208 may be performed by one or more hardware processors configured by machine-readable instructions including a component that is the same as or similar to instruction component 128, in accordance with one or more implementations.

An operation 210 may include transmitting the instructions to the fabrication system. Operation 210 may be performed by one or more hardware processors configured by machine-readable instructions including a component that is the same as or similar to instruction component 128, in accordance with one or more implementations.

Although the present technology has been described in detail for the purpose of illustration based on what is currently considered to be the most practical and preferred implementations, it is to be understood that such detail is solely for that purpose and that the technology is not limited to the disclosed implementations, but, on the contrary, is intended to cover modifications and equivalent arrangements that are within the spirit and scope of the appended claims. For example, it is to be understood that the present technology contemplates that, to the extent possible, one or more features of any implementation can be combined with one or more features of any other implementation.

What is claimed is:

1. A system configured to train a product model to determine a configuration of a prospective product, the system comprising:
electronic storage that stores at least a product model and training information, wherein the training information includes, for individual developed products: (i) object information characterizing a developed product, (ii) product performance information representing performance of the developed product after release, (iii) subject information indicating individual subjects of the developed product, and (iv) subject content information related to content associated with the subject; and
one or more processors configured by machine-readable instructions to:
obtain the product model;
obtain the training information;
train the product model using the training information for the individual developed products by using the object information, the subject information, and the subject content information for the individual developed products as training inputs and the product performance information as training outputs for the individual developed products such that the product model is trained to predict product performance information for prospective products based on object information, subject information, and subject content information for the prospective products; and
store the trained product model to the electronic storage.

2. The system of claim 1, wherein the object information includes a product type, a product specification, a product demographic, and/or manufacturing information for the developed product.

3. The system of claim 1, wherein the product performance information includes a product launch date, a product discontinuation date, revenue from a start date, a volume of sales from the start date, a wholesale manufacturing price, manufacturer's suggest retail price over time from the start date, demographic information of consumers, a geographic region sold, a geographic region with most sales, and one or more retailers that sell the individual previous products.

4. The system of claim 1, wherein the subject information includes a subject definition for the individual subjects and licensed art styles incorporated into or with the subjects, wherein the individual subjects are included in one or more collections.

5. The system of claim 1, wherein the subject content information includes schedules for releases of one or more upcoming or past collections for all media types related to the one or more subjects, one or more budgets for the releases of the upcoming or past collections, wherein the upcoming or past ones of the collections includes one or more subjects.

6. The system of claim 5, wherein the subject content information includes research information including demographic research on upcoming releases of content and/or products related to individual collections, revenue forecast for the releases of the content and/or products, and market shares by product type.

7. A system configured to instruct a fabrication system to generate a product based on a product request, the system comprising:
electronic storage that stores a trained product model trained to predict product performance information based on object information, subject information, and subject content information and recommend at least the object information and the subject information for a prospective product to achieve maximum performance; and
one or more processors configured by machine-readable instructions to:
receive target information for a prospective product, wherein the target information generally characterizes the prospective product as an object and a subject of the object;
transmit the target information to the trained product model so that the trained product model identifies at least object information for the prospective product and/or subject information for the prospective product based on the target information;
receive the object information and/or the subject information; and
generate instructions for a fabrication system to generate the prospective product in accordance with the object information and/or the subject information.

8. The system of claim 7, wherein the target information includes a target demographic, a target price point or manufacturer's suggest retail price range, a product type, an intensity value to implementation of subject definitions, an art style, a weight value for the art style, and/or one or more target collections.

9. The system of claim 7, wherein the trained product model further determines prospective performance information including a target demographic, a target geographic region to offer the prospective product in, a recommended wholesale manufacturing price, a target manufacturer's suggest retail price, a recommended product launch date, an estimated achievable revenue, and an estimated amount of time in market.

10. The system of claim 9, wherein the target geographic region is based on cost to ship to retailers of the target geographic region and/or wage for employees at the retailers.

11. A method to train a product model to determine a configuration of a prospective product, the method comprising:
obtaining a product model, wherein the product model is obtained from electronic storage that stores at least the product model and training information, wherein the training information includes, for individual developed products: (i) object information characterizing a developed product, (ii) product performance information representing performance of the developed product after release, (iii) subject information indicating individual subjects of the developed product, and (iv) subject content information related to content associated with the subject;
obtaining the training information from the electronic storage;
training the product model using the training information for the individual developed products by using the object information, the subject information, and the subject content information for the individual developed products as training inputs and the product performance information as training outputs for the individual developed products such that the product model is trained to predict product performance information for prospective products based on object information, subject information, and subject content information for the prospective products; and
storing the trained product model to the electronic storage.

12. The method of claim 11, wherein the object information includes a product type, a product specification, a product demographic, and/or manufacturing information for the developed product.

13. The method of claim 11, wherein the product performance information includes a product launch date, a product discontinuation date, revenue from a start date, a volume of sales from the start date, a wholesale manufacturing price, manufacturer's suggest retail price over time from the start date, demographic information of consumers, a geographic region sold, a geographic region with most sales, and one or more retailers that sell the individual previous products.

14. The method of claim 11, wherein the subject information includes a subject definition for the individual subjects and licensed art styles incorporated into or with the subjects, wherein the individual subjects are included in one or more collections.

15. The method of claim 11, wherein the subject content information includes schedules for releases of one or more upcoming or past collections for all media types related to the one or more subjects, one or more budgets for the releases of the upcoming or past collections, wherein the upcoming or past ones of the collections includes one or more subjects.

16. The method of claim 15, wherein the subject content information includes research information including demographic research on upcoming releases of content and/or products related to individual collections, revenue forecast for the releases of the content and/or products, and market shares by product type.

17. A method to instruct a fabrication system to generate a product based on a product request, the method comprising:
receiving target information for a prospective product, wherein the target information characterizes the prospective product as an object and a subject of the object;
transmitting the target information to the trained product model, wherein electronic storage stores the trained product model trained to predict product performance information based on object information, subject information, and subject content information and recommend at least the object information and the subject information for a prospective product to achieve maximum performance, so that the trained product model identifies at least object information for the prospective product and/or subject information for the prospective product based on the target information;
receiving the object information and/or the subject information; and
generating instructions for a fabrication system to generate the prospective product in accordance with the object information and/or the subject information.

18. The method of claim 17, wherein the target information includes a target demographic, a target price point or manufacturer's suggest retail price range, a product type, an intensity value to implementation of subject definitions, an art style, a weight value for the art style, and/or one or more target collections.

19. The method of claim 17, wherein the trained product model further determines prospective performance information including a target demographic, a target geographic region to offer the prospective product in, a recommended wholesale manufacturing price, a target manufacturer's suggest retail price, a recommended product launch date, an estimated achievable revenue, and an estimated amount of time in market.

20. The method of claim 19, wherein the target geographic region is based on cost to ship to retailers of the target geographic region and/or wage for employees at the retailers.
